(19) United States
(12) Patent Application Publication
(10) Pub. No.: US 2008/0203856 A1
(43) Pub. Date: Aug. 28, 2008

(54) PIEZOELECTRIC ELEMENT, LIQUID EJECTION HEAD AND PRINTER

(75) Inventor: Hiromu MIYAZAWA, Azumino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/038,016

(22) Filed: Feb. 27, 2008

(30) Foreign Application Priority Data
Feb. 28, 2007 (JP) 2007-048974

(51) Int. Cl. H01L 41/187; B41J 2/045

(52) U.S. Cl. 310/358; 310/360; 347/68

(57) ABSTRACT

A piezoelectric element includes a base substrate; a lower electrode formed above the base substrate; a piezoelectric layer that is formed above the lower electrode, and formed from a perovskite type oxide expressed by a general formula ABO₃, where A includes lead (Pb), and B includes zirconium (Zr) and titanium (Ti); and an upper electrode formed above the piezoelectric layer, wherein the piezoelectric layer has at least two regions having different compositions of Zr with respect to Zr and Ti.

The entire disclosure of Japanese Patent Application No. 2007-048974, filed Feb. 28, 2007 is expressly incorporated by reference herein.

### BACKGROUND

1. Technical Field

The present invention relates to piezoelectric elements, liquid jet heads and printers.

2. Related Art

The ink jet method has been put into practical use as a high resolution and high speed printing method. For ejecting ink droplets, it is useful to employ piezoelectric elements with the structure in which a piezoelectric layer is sandwiched by electrodes. As a representative material for the piezoelectric layer, lead zirconate titanate (Pb (Zr, Ti) O₃: PZT) that is a perovskite type oxide may be enumerated (see, for example, Japanese Laid-open patent application JP-A-2001-223404).

### SUMMARY

In accordance with an advantage of some aspects of the invention, piezoelectric elements that can achieve both improvement in the initial displacement amount and improvement in the durability can be provided. In accordance with another advantage of the aspects of the invention, liquid jet heads and printers having the piezoelectric elements are provided.

A piezoelectric element in accordance with an embodiment of the invention includes: a base substrate; a lower electrode formed above the base substrate; a piezoelectric layer that is formed above the lower electrode, and formed from a perovskite type oxide expressed by a general formula ABO₃, where A includes lead (Pb), and B includes zirconium (Zr) and titanium (Ti); and an upper electrode formed above the piezoelectric layer, wherein the piezoelectric layer has at least two regions having different compositions of Zr with respect to Zr and Ti.

In this piezoelectric element, the piezoelectric layer has regions with different compositions of Zr (hereafter simply referred to as Zr compositions) with respect to Zr and Ti. The regions are hereafter also referred to as “different composition regions.” As a result, the piezoelectric element can attain both improvement in the initial displacement amount and improvement in the durability. This is confirmed by experimental example to be described below.

In accordance with an aspect of the invention, there are three or more different composition regions, and the Zr compositions in the different composition regions are all different from one another.

It is noted that, in the descriptions concerning the invention, the term “above” may be used, for example, as “a specific element (hereafter referred to as “A”) is formed ‘above’ another specific element (hereafter referred to as “B”).” In the descriptions concerning the invention, in this case, the term “above” is assumed to include a case in which A is formed directly on B, and a case in which A is formed above B through another element.

In the piezoelectric element in accordance with an aspect of the embodiment of the invention, the region of the piezoelectric layer may have a first region and a second region formed above the first region, wherein the composition of Zr with respect to Zr and Ti in the first region may be greater than the composition of Zr with respect to Zr and Ti in the second region.

In the piezoelectric element in accordance with an aspect of the embodiment of the invention, the region of the piezoelectric layer may have a greater composition of Zr with respect to Zr and Ti toward a lower portion of the region.

In the piezoelectric element in accordance with an aspect of the embodiment of the invention, the region of the piezoelectric layer may have a layered structure.

In the piezoelectric element in accordance with an aspect of the embodiment of the invention, the piezoelectric layer may be oriented to (100) crystal orientation in the pseudo-cubic crystal expression.

In the invention, the “psuedo-cubic” is a state of a crystal structure that is assumed to be cubic.

In the present invention, being “oriented to (100) crystal orientation” includes the case where the entire crystal is oriented to (100) crystal orientation, and the case where most of the crystals (for example, 90% or more) are oriented to (100) crystal orientation, and the remaining crystals that are not oriented to (100) may be oriented to another crystal orientation, for example, in (111) or the like. In other words, being “oriented to (100) crystal orientation” may be interchangeable with “being preferentially oriented to (100) crystal orientation.”

In the piezoelectric element in accordance with an aspect of the embodiment of the invention, the crystal structure of the piezoelectric layer may be a rhombohedral structure or a monoclinic structure.

In the present invention, the statement “the crystal structure is a rhombohedral structure” includes the case where the entire crystals are in a rhombohedral structure, and the case where most of the crystals (for example, 90% or more) are in a rhombohedral structure, and the remaining crystals that are not in a rhombohedral structure have a tetragonal crystal structure. In accordance with the invention, the above similarly applies to, for example, the statement “the crystal structure is a monoclinic structure.”

A liquid jet head in accordance with an embodiment of the invention has any one of the piezoelectric elements described above.

The liquid jet head in accordance with an aspect of the embodiment of the invention has a nozzle plate having a nozzle aperture connecting to a pressure chamber, and the above-described piezoelectric element formed above the nozzle plate, wherein the pressure chamber may be formed by an opening section in a substrate.

A printer in accordance with an embodiment of the invention includes any one of the piezoelectric elements described above.

A printer in accordance with an embodiment of the invention may include a head unit having the above-described liquid jet head, a head unit driving section that reciprocally moves the head unit, and a controller section that controls the head unit and the head unit driving section.

### BRIEF DESCRIPTION OF THE DRAWINGS

FIG. 1 is a schematic cross-sectional view of a piezoelectric element in accordance with an embodiment of the invention.

FIG. 2 is a schematic cross-sectional view showing a step of a method for manufacturing a piezoelectric element in accordance with an embodiment of the invention.

FIG. 3 is a schematic exploded perspective view of a liquid jet head in accordance with an embodiment of the invention.

FIG. 4 shows a simulation result showing the relation between positions within a piezoelectric layer and tensile stresses therein.

FIG. 5 is a schematic cross-sectional view of a piezoelectric element in accordance with a first modified example of the embodiment of the invention.

FIG. 6 is a schematic perspective view of a printer in accordance with an embodiment of the invention.

### DESCRIPTION OF EXEMPLARY EMBODIMENTS

Preferred embodiments of the invention are described below with reference to the accompanying drawings.

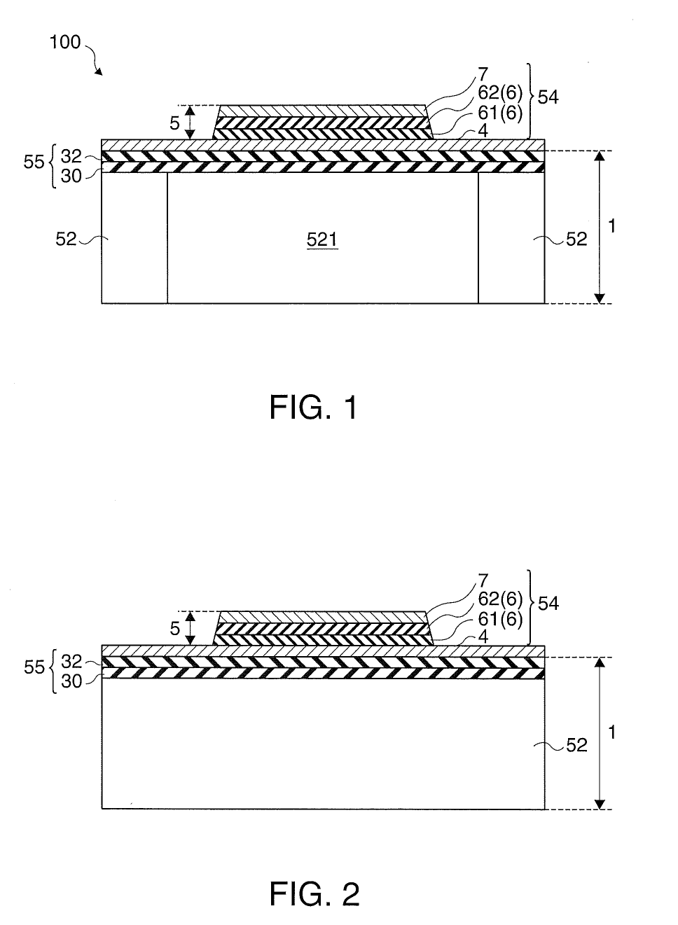

1. First, a piezoelectric element 100 in accordance with an embodiment of the invention is described. FIG. 1 is a schematic cross-sectional view of the piezoelectric element 100.

As shown in FIG. 1, the piezoelectric element 100 includes a base substrate 1 and a driving section 54. The base substrate 1 may have a substrate 52 and an elastic plate 55.

As the substrate 52, for example, a (110) single crystal silicon substrate (with a plane orientation <110>) may be used. The substrate 52 has an opening section 521. The opening section 521 may form, for example, a pressure chamber of an ink jet recording head. The shape of the opening section 521 is, for example, a cuboid that is 60 μm wide, 1 mm long and 60 μm high.

The elastic plate 55 is formed on the substrate 52. The elastic plate 55 may include, for example, an etching stopper layer 30, and an elastic layer 32 formed on the etching stopper layer 30. The etching stopper layer 30 may be formed from, for example, silicon oxide (SiO₂). The thickness of the etching stopper layer 30 is, for example, 1 μm. The elastic layer 32 may be formed from, for example, zirconium oxide (ZrO₂). The thickness of the elastic layer 32 is, for example, 1 μm. It is noted that the flexible plate 55 may be provided without the etching stopper layer 30 (though its illustration is not shown).

The driving section 54 is formed on the elastic plate 55. The driving section 54 is capable of flexing the elastic plate 55. The driving section 54 may include a lower electrode 4 formed on the elastic plate 55 (more specifically, on the elastic layer 32), a piezoelectric layer 6 formed on the lower electrode 4, and an upper electrode 7 formed on the piezoelectric layer 6. The major portion of the driving section 54 is formed above, for example, the opening section 521, and a portion of the driving section 54 (more specifically, the lower electrode 4) may also be formed on the substrate 52, for example.

The lower electrode 4 is one of electrodes for applying a voltage to the piezoelectric layer 6. As the lower electrode 4, for example, a platinum (Pt) layer (with 200 nm thick) may be used.

The piezoelectric layer 6 is composed of a perovskite type oxide that is expressed by a general formula ABO₃, where A (the element A: A site) includes lead (Pb), B (the element B: B site) includes zirconium (Zr) and titanium (Ti). More specifically, the piezoelectric layer 6 may be composed of piezoelectric material, such as, for example, lead zirconate titanate (Pb (Zr, Ti) O₃: PZT), and lead zirconate titanate solid solution. As the lead zirconate titanate solid solution, for example, lead zirconate titanate niobate (Pb (Zr, Ti, Nb) O₃: PZTN) may be used. Also, a second composition other than lead (Pb), for example, lanthanum (La), neodymium (Nd) or the like may be added to the A site. Further, other elements, such as, for example, barium (Ba), pottasium (Ca) and the like may be added in a very small amount to the A site.

The piezoelectric layer 6 has regions (different composition regions) with different compositions of Zr (hereafter referred to as Zr compositions) with respect to Zr and Ti. In the illustrated example, the piezoelectric layer 6 has two different composition regions, which may be made of a first region 61 and a second region 62 formed directly on the first region 61. In the illustrated example, the piezoelectric layer 6 is formed from the first region 61 and the second region 62.

The Zr composition of the first region 61 may preferably be greater than the Zr composition of the second region 62. For example, when the piezoelectric layer 6 is composed of lead zirconate titanate (Pb (ZrₓTi₁₋ₓ) O₃), the Zr composition x of the first region 61 is, for example, 0.55, and the Zr composition x of the second region 62 is, for example, 0.5.

The different composition regions (the first region 61 and the second region 62 in the illustrated example) of the piezoelectric layer 6 may be, for example, in a layered structure. The thickness ratio of the multiple different composition regions may be appropriately decided. In the illustrated example, the ratio of the thickness of the first region 61 to the thickness of the second region 62 may be set to 1:1, for example. More specifically, the thickness of the first region 61 of the piezoelectric layer 6 is, for example, 500 nm, and the thickness of the second region 62 of the piezoelectric layer 6 is, for example, 500 nm. Also, the entire thickness of the piezoelectric layer 6 is, for example, 1 μm.

The piezoelectric layer 6 may preferably be oriented to (100) crystal orientation in the pseudo-cubic crystal expression. The crystal structure of the piezoelectric layer 6 may preferably be a rhombohedral structure or a monoclinic structure. This crystal structure corresponds to an engineered domain structure in which the piezoelectric displacement reaches a maximum amount when the direction of polarization moment is tilted at a specific angle with respect to the application direction of electrical fields.

The upper electrode 7 is the other electrode for applying a voltage to the piezoelectric layer 6. As the upper electrode 7, for example, a platinum (Pt) layer (with 200 nm thick) may be used.

The piezoelectric layer 6 and the upper electrode 7 may form, for example, a columnar laminate (columnar section) 5. The width of the columnar section 5 (the width of the lower surface of the piezoelectric layer 6) is, for example, 40 μm, and the length of the columnar section 5 (the length of the lower surface of the piezoelectric layer 6) is, for example, 1 μm.

2. Next, a method for manufacturing a piezoelectric element 100 in accordance with an embodiment of the invention is described. FIG. 2 is a schematic cross-sectional view showing a step of the method for manufacturing the piezoelectric element 100 in accordance with the embodiment, which corresponds to the cross-sectional view shown in FIG. 1.

(1) First, as shown in FIG. 2, the elastic plate 55 is formed on the substrate 52. More specifically, for example, the etching stopper layer 30 and the elastic layer 32 are successively formed in this order over the entire surface of the substrate 52. By this step, the elastic plate 55 having the etching stopper layer 30 and the elastic layer 32 is formed. The etching stopper layer 30 may be formed by, for example, a thermal oxidation method. The elastic layer 32 may be formed by, for example, a CVD (chemical vapor deposition) method.

(2) Next, as shown in FIG. 2, the driving section 54 is formed on the elastic plate 55. More specifically, first, the lower electrode 4, the piezoelectric layer 6 and the upper electrode 7 are successively formed in this order over the entire surface of the elastic plate 55. The lower electrode 4 and the upper electrode 7 may be formed by, for example, a sputter method, a plating method or the like.

The piezoelectric layer 6 may be formed by a sol-gel method (solution method), a MOD (metal organic decomposition) method, a sputter method, a laser ablation method or the like. As an example, the case where the piezoelectric layer 6 composed of PZT is formed by a sol-gel method is described below.

First, a solution (of piezoelectric materials) in which organometallic compounds respectively containing Pb, Zr and Ti are dissolved in a solvent is coated on the entire surface of the lower electrode 4 by a spin coat method. For example, by changing the mixing ratio of the organometallic compounds respectively containing Zr and Ti in the solution, the composition ratio of Zr and Ti (Zr:Ti) can be adjusted. For example, the organometallic compounds may be mixed such that the Zr composition=Zr/(Zr+Ti) equals to 0.55. It is noted that the composition of Pb can also be adjusted by changing the mixing ratio of the organometallic compounds.

Next, by conducting a heat treatment (for drying step and degreasing step), a precursor layer for the first region 61 of the piezoelectric layer 6 can be formed. The temperature of the drying step may preferably be, for example, 150° C. or higher but 200° C. or lower. Also, the time for drying step may preferably be, for example, 5 minutes or longer. In the degreasing step, organic components remaining in the PZT precursor layer after the drying step may be thermally decomposed into NO₂, CO₂, H₂O and the like and thus removed. The temperature of the degreasing step may be, for example, about 300° C.

Next, like the film formation of the precursor layer for the first region 61 described above, the steps of coating a piezoelectric material, drying and degreasing may be conducted, whereby a precursor layer for the second region 62 of the piezoelectric layer 6 can be formed. In this instance, the Zr composition of the piezoelectric material may be, for example, 0.50.

It is noted that, in forming the precursor layer for the first region 61, the precursor layer may be formed in a plurality of divided rounds, not all at once. More specifically, for example, a series of the steps of coating of the piezoelectric material, drying and degreasing may be repeated multiple times. This similarly applies to the step of forming the precursor layer for the second region 62.

Next, the precursor layer for the first region 61 and the precursor layer for the second region 62 may be sintered all at once. In this sintering step, the PZT precursor layers are heated and thereby crystallized. The temperature for the sintering step may be, for example, 600° C. to 700° C. The time for the sintering step may preferably be 5 minutes or longer but 30 minutes or shorter. The apparatus that may be used for the sintering step includes, without any particular limitation, a diffusion furnace, a RTA (rapid thermal annealing) apparatus, or the like. It is noted that the sintering step may be conducted, for example, at each one cycle of coating the piezoelectric material, drying and degreasing.

By the steps described above, the piezoelectric layer 6 formed from, for example, the first region 61 and the second region 62 can be formed.

Next, for example, the upper electrode 7 and the piezoelectric layer 6 are patterned, thereby forming the columnar section 5 in a desired shape. Then, for example, the lower electrode 4 may be patterned. Each of the layers may be patterned by using, for example, lithography technique and etching technique. The lower electrode 4, the piezoelectric layer 6 and the upper electrode 7 may be patterned independently as each of the layers is formed, or together as each set of plural layers is formed.

By the steps described above, the driving section 54 having the lower electrode 4, the piezoelectric layer 6 and the upper electrode 7 is formed.

(3) Next, as shown in FIG. 1, the substrate 52 is patterned, thereby forming the opening section 521. The substrate 52 may be patterned by using, for example, lithography technique and etching technique. The opening section 521 may be formed by, for example, etching a portion of the substrate 52 in a manner to expose the etching stopper layer 30. In this etching step, the etching stopper layer 30 may be functioned as a stopper to the etching. In other words, when the substrate 52 is etched, the etching rate of the etching stopper layer 30 is lower than the etching rate of the substrate 52.

By the steps described above, as shown in FIG. 1, the piezoelectric element 100 in accordance with the present embodiment is fabricated.

3. In the piezoelectric element 100 in accordance with the present embodiment, the piezoelectric layer 6 has regions (different composition regions) 61 and 62 with different Zr compositions. By this, the piezoelectric element 100 in accordance with the present embodiment can attain both improvement in the initial displacement amount and improvement in the durability. This is confirmed by experimental examples to be described below.

4. A liquid jet head having the above-described piezoelectric element is described. Here, an example in which the liquid jet head 50 in accordance with the present embodiment is an ink jet type recording head is described.

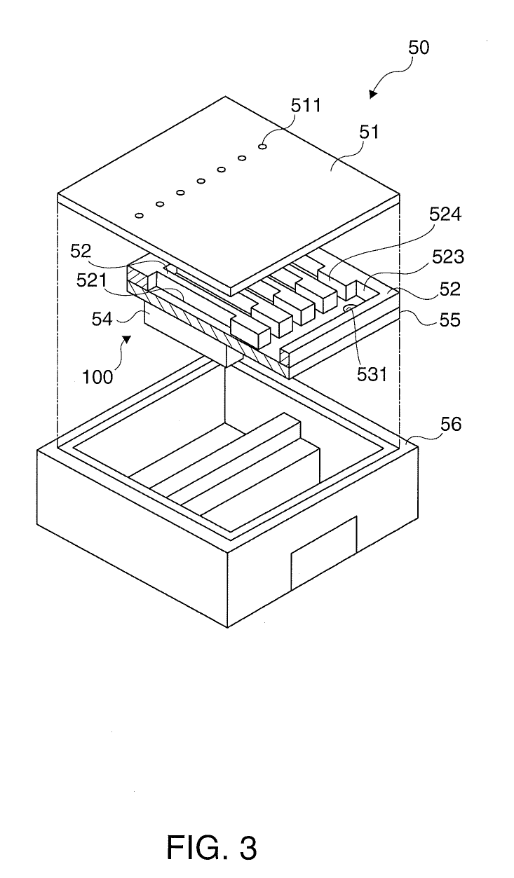

FIG. 3 is a schematic exploded perspective view of the liquid jet head 50 in accordance with the embodiment of the invention, and shows the head upside down with respect to a state in which it is normally used. It is noted that the illustration of the driving section 54 of the piezoelectric element 100 is simplified in FIG. 3 for the sake of convenience.

The liquid jet head 50 includes the piezoelectric element 100 shown, for example, in FIG. 1, and the nozzle plate 51. The liquid jet head 50 may further include a housing 56.

The nozzle plate 51 has nozzle holes 511 connecting to a pressure chamber 521. Ink is ejected through the nozzle holes 511. The nozzle plate 51 may be provided with, for example, a row of multiple nozzle holes 511. The nozzle plate 51 is formed from, for example, a rolled plate of stainless steel (SUS). The nozzle plate 51 is affixed to a lower side (an upper side in the illustration of FIG. 3) of the substrate 52 in the sate in which it is normally used. The housing 56 can store the nozzle plate 51 and the piezoelectric elements 100. The housing 56 may be formed with, for example, any one of various resin materials or any one of various metal materials.

The substrate 52 of the piezoelectric element 100 divides the space between the nozzle plate 51 and the elastic plate 55, thereby defining a reservoir (liquid reserving section) 523, supply ports 524 and a plurality of cavities (pressure chambers) 521. The elastic plate 55 of the piezoelectric element 100 is provided with a through-hole 531 that penetrates the elastic plate 55 in its thickness direction. The reservoir 523 temporarily stores ink that is supplied from the outside (for example, from an ink cartridge) through the through-hole 531. Ink is supplied to each of the cavities 521 from the reservoir 523 through each of the corresponding supply ports 524.

Each of the cavities 521 is formed from an opening section 521 of the substrate 52. Each one of the cavities 521 is provided for each one of the nozzles 511. The cavity 521 is capable of changing its volume by deformation of the elastic plate 55. The volume change causes ink to be ejected from the cavity 521.

The driving section 54 is electrically connected to a piezoelectric element driving circuit (not shown), and is capable of operating (vibrating, deforming) based on signals provided by the piezoelectric element driving circuit. The elastic layer 55 deforms by deformation of the driving section 54, and can instantaneously increase the inner pressure of the cavity 521.

The aforementioned example is described with reference to the case where the liquid jet head 50 is an ink jet type recording head. However, the liquid jet head in accordance with the invention is also applicable as, for example, a color material jet head used for manufacturing color filters for liquid crystal displays and the like, an electrode material jet head used for forming electrodes for organic EL displays, FED (Field Emission Displays) and the like, and a bioorganic material jet head used for manufacturing bio-chips.

5. Next, experimental examples are described.

As experimental examples, a liquid jet head 50 having the piezoelectric element 100 in accordance with the present embodiment, and liquid jet heads in accordance with comparison examples 1-3 were manufactured.

The piezoelectric layer 6 of the piezoelectric element 100 in accordance with the present embodiment was formed with a first region 61 and a second region 62, as shown in FIG. 1. The first region 61 was composed of Pb (Zr_{0.55}Ti_{0.45})O₃) (which means that the Zr composition=0.55), and the second region 62 was composed of Pb (Zr_{0.50}Ti_{0.50})O₃) (which means that the Zr composition=0.50).

In contrast, each of the piezoelectric layers of the piezoelectric elements in accordance with the comparison examples 1-3 was formed with a single layer of PZT. The Zr compositions of the piezoelectric layers of the comparison examples 1-3 were changed from 0.45 to 0.55 by an increment of 0.05.

Pulse voltages that change between −2V and 35V at 50 kHz were applied 2×10¹⁰ (20 billion) times to the upper and lower electrodes of the experimental samples, whereby durability tests were conducted. Table 1 below shows the amount of displacement of the elastic plate at the beginning and at the end, and the durability of the piezoelectric element. It is noted that the durability of the piezoelectric element (%)={(the amount of displacement of the elastic plate at the end−the amount of the elastic plate at the beginning)/the amount of the elastic plate at the beginning}×100.

TABLE 1

| | Present | Comparison | Comparison | Comparison |
|---|---|---|---|---|
| | Embodiment | Example 1 | Example 2 | Example 3 |
| Zr composition | 0.5/0.55 | 0.45 | 0.5 | 0.55 |
| Amount of | 430 | 530 | 450 | 380 |
| displacement at | | | | |
| the beginning | | | | |
| (nm) | | | | |
| Amount of | 420 | 420 | 410 | 370 |
| displacement at | | | | |
| the end (nm) | | | | |
| Durability (%) | −2.3 | −20.8 | −8.9 | −2.6 |

As shown in Table 1, the comparison example 1 and the comparison example 2 each with a low Zr composition have a relatively large amount of piezoelectric displacement at the beginning, but their durability is low. The comparison example 3 with a relatively high Zr composition has a smaller amount of piezoelectric displacement at the beginning, but its durability is controlled to about −3%. In contrast, with the piezoelectric element 100 in accordance with the present embodiment, the amount of displacement of the elastic plate at the beginning is greater than that of the piezoelectric element of the comparison example 3, and is close to that of the piezoelectric element of the comparison example 2. Further, the durability of the piezoelectric element 100 in accordance with the present embodiment is improved better than that of the piezoelectric element of the comparison example 2, and is close to that of the piezoelectric element of the comparison example 3. Therefore, it was confirmed that, according to the piezoelectric element 100 in accordance with the present embodiment, improvement in the amount of displacement of the elastic plate at an initial stage of repetitious operations and improvement in the durability (in other words, suppression of reduction in the amount of displacement of the elastic plate) can both be achieved. The following reasons may be attributable to the above.

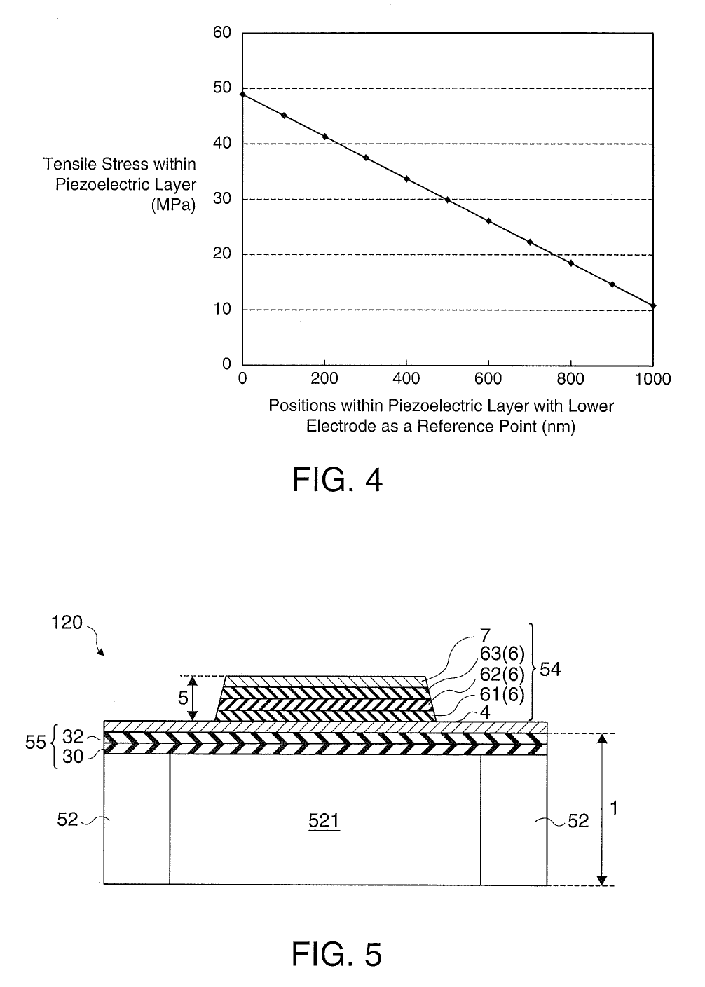

FIG. 4 shows results of the relation between positions within a piezoelectric layer wherein the piezoelectric layer is composed of a single layer of PZT with the lower electrode as being a reference point, and tensile stresses within the piezoelectric layer at the time of voltage application, which were obtained by simulation. For the simulation, it was assumed that the nozzle plate was made of stainless steel (SUS), and its Young's modulus was 170 GPa. The substrate was made of Si, and its Young's modulus was 150 GPa. Also, the etching stopper layer was made of SiO₂, and its Young's modulus was 75 GPa. Further, the elastic layer was made of ZrO₂, and its Young's modulus was 150 GPa. The lower electrode was made of Pt, and its Young's modulus was 200 GPa. The piezoelectric layer was made of PZT, and its Young's modulus was 70 GPa. The upper electrode was made of Pt, and its Young's modulus was 200 GPa. Also, in the simulation, it was assumed that the piezoelectric layer had a 0.1% piezoelectric displacement.

According to the results of the simulation, it is observed that, in the piezoelectric layer at the time of operation, the tensile stress at the lower electrode side is greater and the tensile stress at the upper electrode side is smaller. Also, as shown by the results for the comparison examples 1-3 in Table 1, the greater the Zr composition of the piezoelectric layer, the better the durability becomes; and the smaller the Zr composition, the greater the amount of initial displacement becomes. Within the piezoelectric element 6 in accordance with the present embodiment, the first region 61 with a greater Zr composition and excellent durability is provided on the side of the lower electrode 4 where a greater load is applied. By this, it is believed that the durability can be effectively improved. Furthermore, within the piezoelectric element 6 in accordance with the present embodiment, the second region 62 with a smaller Zr composition is provided on the side of the upper electrode 7 where a smaller tensile stress is generated. By this, the amount of initial displacement of the elastic plate can be effectively increased. It is thus believed that, by the piezoelectric element 100 in accordance with the present embodiment, improvement in the durability and improvement in the amount of initial displacement can both be effectively achieved.

Also, the crystal structure of the piezoelectric layer 6 in accordance with the present embodiment obtained by the above-described experimental example was confirmed to be a perovskite type structure, which had a rhombohedral structure or a monoclinic structure. Also, it was confirmed that the piezoelectric layer 6 in accordance with the present embodiment was oriented to (100) crystal orientation in the pseudo-cubic crystal expression. The crystal structure and crystal orientation of the piezoelectric layer 6 were judged by using X-ray scattering and Raman scattering.

6. Next, modified examples of the piezoelectric element in accordance with the present embodiment are described with reference to the accompanying drawings. It is noted that aspects different from those of the above-described piezoelectric element 100 (hereafter referred to as the “example of piezoelectric element 100”) shown in FIG. 1 are described, and descriptions of the same aspects are omitted.

(1) First, a first modified example is described. FIG. 5 is a schematic cross-sectional view of a piezoelectric element 120 in accordance with the present modified example.

According to the example of piezoelectric element 100, the case where the piezoelectric layer is formed from two regions of different Zr compositions (different composition regions), in other words, is formed form the first region 61 and the second region 62, is described. However, there may be, for example, three or more different composition regions. For example, as shown in FIG. 5, three different composition regions, in other words, a first region 61, a second region 62 and a third region may be provided. In this case, the Zr compositions of the different composition regions 61, 62 and 63 are different from one another. The Zr composition may preferably be greater in a lower one of the different composition regions 61, 62 and 63. This is because, as shown by the aforementioned simulation results, the tensile stress is greater in a lower portion within the piezoelectric layer 6.

(2) Next, a second modified example is described.

In the example of piezoelectric element 100, the case where the piezoelectric layer is formed from the first region 61 and the second region 62 formed on the first region 61, and the Zr composition of the first region 61 is greater than the Zr composition of the second region 62 is described. However, the Zr composition of the first region 61 may be made smaller than the Zr composition of the second region 62, for example, if the tensile stress becomes greater in an upper portion within the piezoelectric layer 6. By this, for example, a region with a greater Zr composition having excellent durability may be arranged in a portion where the tensile stress is greater, and a region with a smaller Zr composition capable of causing a greater amount of initial displacement may be arranged in a portion where the tensile stress is smaller.

(3) Next, a third modified example is described.

According to the example of piezoelectric element 100, the case where the piezoelectric layer 6 is formed from two different composition regions 61 and 62 is described. However, the piezoelectric layer 6 may have a region that is not a different composition region in addition to the different composition regions 61 and 62. For example, although not shown, the piezoelectric layer 6 may be formed from a first region 61, a second region 62 and another region that is formed on the second region 62 and has the same Zr composition as that of the first region 61.

(4) It is noted that the aforementioned modified examples are only examples, and the invention is not limited to those modified example. For example, the modified examples may be appropriately combined together.

7. A printer having the above-described liquid jet head is described. The case where a printer 600 in accordance with the present embodiment is an ink jet printer is described.

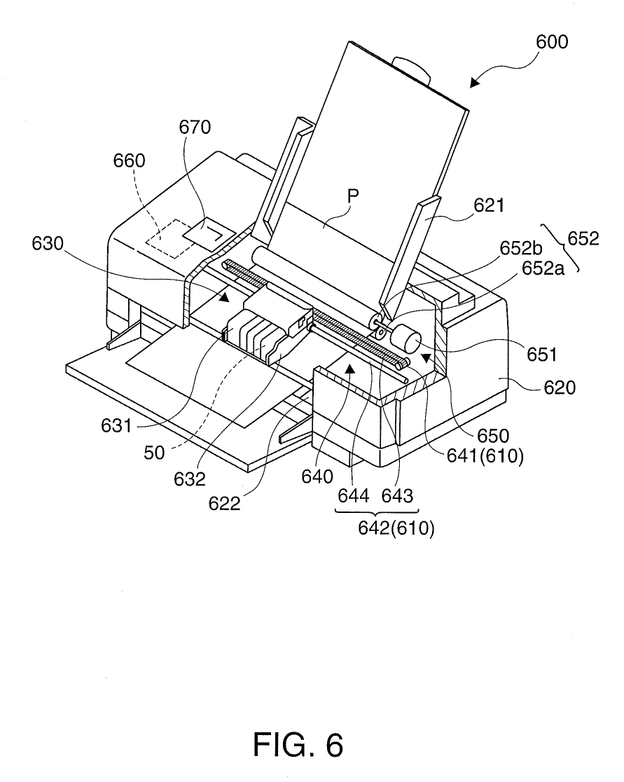

FIG. 6 is a schematic perspective view of a printer in accordance with an embodiment of the invention. The printer 600 includes a head unit 630, a head unit driving section 610, and a controller section 660. Also, the printer 600 may include an apparatus main body 620, a paper feed section 650, a tray 621 for holding recording paper P, a discharge port 622 for discharging the recording paper P, and an operation panel 670 disposed on an upper surface of the apparatus main body 620.

The head unit 630 includes an ink jet type recording head (hereafter simply referred to as the “head”) 50 formed from the above-described liquid jet head. The head unit 630 is further quipped with ink cartridges 631 that supply inks to the head 50, and a transfer section (carriage) 632 on which the head 50 and the ink cartridges 631 are mounted.

The head unit driving section 610 is capable of reciprocally moving the head unit 630. The head unit driving section 610 includes a carriage motor 641 that is a driving source for the head unit 630, and a reciprocating mechanism 642 that receives rotations of the carriage motor 641 to reciprocate the head unit 630.

The reciprocating mechanism 642 includes a carriage guide shaft 644 with its both ends being supported by a frame (not shown), and a timing belt 643 that extends in parallel with the carriage guide shaft 644. The carriage 632 is supported by the carriage guide shaft 644, in a manner that the carriage 632 can be freely reciprocally moved. Further, the carriage 632 is affixed to a portion of the timing belt 643. By operations of the carriage motor 641, the timing belt 643 is moved, and the head unit 630 is reciprocally moved, guided by the carriage guide shaft 644. During these reciprocal movements, the ink is jetted from the head 50 and printed on the recording paper P.

The control section 660 can control the head unit 630, the head unit driving section 610 and the paper feeding section 650.

The paper feeding section 650 can feed the recording paper P from the dray 621 toward the head unit 630. The paper feeding section 650 includes a paper feeding motor 651 as its driving source and a paper feeding roller 652 that is rotated by operations of the paper feeding motor 651. The paper feeding roller 652 is equipped with a follower roller 652a and a driving roller 652b that are disposed up and down and opposite to each other with a feeding path of the recording paper P being interposed between them. The driving roller 652b is coupled to the paper feeding motor 651.

The head unit 630, the head unit driving section 610, the control section 660 and the paper feeding section 650 are provided inside the apparatus main body 620.

It is noted that the examples in which the printer 600 is an ink jet printer are described above. However, the printer in accordance with the invention is also applicable to an industrial liquid jet apparatus. As the liquid (liquid material) to be jetted in this case, a variety of liquids each containing a functional material whose viscosity is adjusted by a solvent or a disperse medium may be used.

8. Embodiments of the invention are described above in detail. However, those having ordinary skill in the art should readily understand that many modifications can be made without departing in substance from the new matters and effects of the invention. Accordingly, all of those modified examples should also be included in the scope of the invention.

For example, the above-described piezoelectric elements in accordance with the embodiments of the invention are applicable to piezoelectric transducers that may be used for oscillators and frequency filters, angular velocity sensors that may be used for digital cameras, navigation systems, and the like.

What is claimed is:

1. A piezoelectric element comprising:
a base substrate;
a lower electrode formed above the base substrate;
a piezoelectric layer that is formed above the lower electrode, and formed from a perovskite type oxide expressed by a general formula ABO₃, where A includes lead (Pb), and B includes zirconium (Zr) and titanium (Ti); and
an upper electrode formed above the piezoelectric layer,
wherein the piezoelectric layer has at least two regions having different compositions of Zr with respect to Zr and Ti.

2. A piezoelectric element according to claim 1, wherein the region of the piezoelectric layer has a first region and a second region formed above the first region, wherein the composition of Zr with respect to Zr and Ti in the first region is greater than the composition of Zr with respect to Zr and Ti in the second region.

3. A piezoelectric element according to claim 1, wherein the region of the piezoelectric layer has a greater composition of Zr with respect to Zr and Ti toward a lower portion of the region.

4. A piezoelectric element according to claim 1, wherein the region of the piezoelectric layer has a layered structure.

5. A piezoelectric element according to claim 1, wherein the piezoelectric layer is oriented to (100) crystal orientation in the pseudo-cubic crystal expression.

6. A piezoelectric element according to claim 1, wherein the crystal structure of the piezoelectric layer has one of a rhombohedral structure and a monoclinic structure.

7. A liquid jet head comprising the piezoelectric element recited in claim 1.

8. A printer comprising the piezoelectric element recited in claim 1.
